(19) United States
(12) Patent Application Publication
(10) Pub. No.: US 2007/0014137 A1
(43) Pub. Date: Jan. 18, 2007

(54) Banked cache with multiplexer

(76) Inventors: Todd W. Mellinger, Fort Collins, CO (US); Vincent R. Freytag, Windsor, CO (US); Donald R. Weiss, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/183,545

(22) Filed: Jul. 18, 2005

(51) Int. Cl. G11C 15/00; G11C 7/10

(52) U.S. Cl. 365/49; 365/189.02

(57) ABSTRACT

Systems and methods associated with cache banking are described. One exemplary system embodiment includes an array that is physically banked into multiple banks. While inputs may be provided to the banked array at a first rate, an array access may take more than one cycle at that first rate to complete. To facilitate having the banked array appear to handle the inputs at the first rate, the example system may also include a multiplexer that is operably connected to the banks and that may be configured to provide a data value associated with an earlier access to the banks from a particular bank.

### BACKGROUND

Prior Art FIG. 1 illustrates a conventional basic set associative cache 100. Inputs 102 that include address, data, and/or control information may be provided to the cache 100. In a conventional cache, there may be both a tag array 120 and a data array 130. High frequency accesses (e.g., at chip frequency) to cache 100 become more difficult as these arrays get larger, as RAM (random access memory) cells get smaller, as chip frequency increases, and so on. Thus, while logic providing inputs 102 may operate at a chip frequency, logic inside cache 100 may operate more slowly than the chip frequency and thus cache 100 may not be able to accept inputs 102 at a frequency at which they could be provided. Therefore a cache may become a bottleneck in a system.

As arrays like tag array 120 and data array 130 have increased in size, designers may have decided to bank the arrays to address the bottleneck. For example, even/odd address banks in arrays in caches are well known. However, simply banking an array may not adequately resolve speed and/or frequency issues and may create new issues associated with power, space, costs, and so on. These new issues may be exacerbated by conventional cache array banking approaches that duplicate logic like control logic, lines like address/data/control lines, and other items. In caches with duplicated hardware, each bank may have identical hardware and may be independent of other banks. While a bank may handle a request at less than a chip frequency, having multiple banks facilitates handling requests at a rate closer to the chip frequency. However, the additional hardware and duplicate control circuitry for each bank can be prohibitive in space and power consumed.

Cache banking may be employed in systems where inputs are received at a frequency exceeding the frequency at which they can be handled. To facilitate handling these inputs, a cache may switch between banks allowing array accesses to occur partially in parallel. Thus, a memory logic may latch (e.g., store for one or more clock cycles) inputs received so that as time moves on and new requests are received the memory has information available about what the memory is supposed to do. Conventionally, if the inputs are not latched, then new address/data/control information associated with a second bank may destroy (e.g., overwrite) address/data/control information associated with a first bank.

The inputs 102 may be addresses that are provided to a decoder 110 that separates out row and column information for the tag array 120 and/or data array 130. When the arrays are banked, the decoder 110 may also separate out bank identifying information. The row and column information is used to select word lines 140 and bit lines 150 involved in accessing a desired memory location. Data retrieved from a desired memory location may transit column multiplexers 160, be amplified by sense amplifiers 170, and so on. Data from a tag array 120 may additionally be processed by comparators 180 to determine whether a tag way hit occurred. Ultimately, data may transit output drivers 190 and/or multiplexer drivers 195 before being provided as a data output 199, a valid output signal 197, and so on.

Implementing multiple banks in tag array 120 and/or data array 130 with duplicated control and other elements may provide an incomplete solution to resolving issues between chip frequency and memory access times. This incomplete solution may also create new power, heat, and/or chip real estate issues.

### BRIEF DESCRIPTION OF THE DRAWINGS

The accompanying drawings, which are incorporated in and constitute a part of the specification, illustrate various example system and method embodiments of various aspects of the invention. It will be appreciated that the illustrated element boundaries (e.g., boxes, groups of boxes, or other shapes) in the figures represent one example of the boundaries. One of ordinary skill in the art will appreciate that in some examples one element may be designed as multiple elements or that multiple elements may be designed as one element. In some examples, an element shown as an internal component of another element may be implemented as an external component and vice versa. Furthermore, elements may not be drawn to scale.

Prior Art FIG. 1 illustrates a basic conventional set associative cache structure.

FIG. 2 illustrates an example cache.

FIG. 3 illustrates another example cache.

FIG. 4 illustrates another example cache.

FIG. 5 illustrates elements of an example cache.

FIG. 6 illustrates an example method associated with a banked cache.

FIG. 7 illustrates another example method associated with a banked cache.

FIG. 8 illustrates another example method associated with a banked cache.

### DETAILED DESCRIPTION

Example systems and methods described herein relate to banking an array in a cache. In one example, a single set of input lines (e.g., address/control/data) may provide inputs at a chip frequency to a cache. The cache may include an array (e.g., tag way). The array may be physically banked into multiple banks and the banks may be selectable on address bits. For example, even/odd banks may be identified by one address bit, four banks may be identified by two bits, and so on. In one example, address precode/decode may be shared. When a bank in the banked array is accessed, the array access may take a period of time equal to multiple cycles at the chip frequency. For example, in an array that takes two cycles, during a first cycle a word line may fire and a bit line differential may begin to form and during a second cycle a sense amplifier strobe may fire, which enables a sense amplifier, and data may be propagated through the sense amplifier and thus out into a data path. In the example, separate global input lines may be available to each bank and separate global output lines may be provided from each bank.

Unlike conventional banked arrays, control and other components may not be duplicated to facilitate resolving chip frequency versus array access time issues. Instead, array outputs may be operably connected to a multiplexer that can be controlled with respect to when to sample a bank to facilitate providing at a desired output time a data provided by a bank in response to a certain input. In one example, array outputs may be latched at the logical edge of an array and the additional multiplexer may be operably connected to the logical edge latches and controlled to facilitate providing at the desired output time a data provided by a bank in response to a certain input. If input control logic is designed to not provide inputs that require accessing the same bank consecutively, then the additional multiplexer allows the cache to appear as though it is operating at the chip frequency, even though array accesses still require a period of time equivalent to multiple cycles at the chip frequency. Thus the cache may appear to operate at the chip frequency if the number of banks is greater than or equal to the number of clock frequency cycles required to do a banked array access. Additionally, the cache does not require input/output line duplication. Rather, a single set of input lines and a single set of output lines can be employed.

As used herein, “latch” refers to an electronic component configured to store a data value. The output of the latch equals the value stored in the latch. “Logical edge” is intended to convey that the latch operates between the storage function provided by an array and logic associated with post-retrieval processing. Thus, “logical” conveys that different physical electronic components may perform a latching function. For example, a word line driver may perform a latch function. In some cases, data may be “latched” in a sense amplifier.

In one example, a banked cache with an additional multiplexer may have only a tag array. In the tag array example, additional bits in the tag array may store “data” to be provided by the tag array. Thus, additional logic located logically downstream from the additional multiplexer may process the provided data. The processing may include, for example, error correction code (ECC) processing, tag matching, and so on. Since the banked cache appears to operate at chip frequency by switching between banks to handle input requests partially in parallel, this additional post-multiplexer logic may also operate at chip frequency. While a tag array example is described, it is to be appreciated that components including logical edge latches and an additional multiplexer, for example, may be employed with other caches including one with a simple data array.

The following includes definitions of selected terms employed herein. The definitions include various examples and/or forms of components that fall within the scope of a term and that may be used for implementation. The examples are not intended to be limiting. Both singular and plural forms of terms may be within the definitions.

“Logic”, as used herein, includes but is not limited to hardware, firmware, software and/or combinations of each to perform a function(s) or an action(s), and/or to cause a function or action from another logic, method, and/or system. For example, based on a desired application or needs, logic may include a software controlled microprocessor, discrete logic like an application specific integrated circuit (ASIC), an analog circuit, a digital circuit, a programmed logic device, a memory device containing instructions, and so on. Logic may include one or more gates, combinations of gates, or other circuit components. Logic may also be fully embodied as software. Where multiple logical logics are described, it may be possible to incorporate the multiple logical logics into one physical logic. Similarly, where a single logical logic is described, it may be possible to distribute that single logical logic between multiple physical logics.

An “operable connection”, or a connection by which entities are “operably connected”, is one in which signals, physical communications, and/or logical communications may be sent and/or received. Typically, an operable connection includes a physical interface, an electrical interface, and/or a data interface, but it is to be noted that an operable connection may include differing combinations of these or other types of connections sufficient to allow operable control. Two entities can be considered to be operably connected if they are able to communicate signals to each other directly or through one or more intermediate entities including a processor, an operating system, a logic, software, or other entity, for example. Logical and/or physical communication channels can be used to create an operable connection.

“Signal”, as used herein, includes but is not limited to one or more electrical or optical signals, analog or digital signals, data, one or more computer or processor instructions, messages, a bit or bit stream, or other means that can be received, transmitted and/or detected.

Some portions of the detailed descriptions that follow are presented in terms of algorithms and symbolic representations of operations on data bits within a memory. These algorithmic descriptions and representations are the means used by those skilled in the art to convey the substance of their work to others. An algorithm is here, and generally, conceived to be a sequence of operations that produce a result. The operations may include physical manipulations of physical quantities. Usually, though not necessarily, the physical quantities take the form of electrical or magnetic signals capable of being stored, transferred, combined, compared, and otherwise manipulated in a logic and the like.

It has proven convenient at times, principally for reasons of common usage, to refer to these signals as bits, values, elements, symbols, characters, terms, and numbers, for example. It should be borne in mind, however, that these and similar terms are to be associated with the appropriate physical quantities and are merely convenient labels applied to these quantities. Unless specifically stated otherwise, it is appreciated that throughout the description, terms including processing, computing, calculating, determining, and displaying for example, refer to actions and processes of a computer system, logic, processor, or similar electronic device that manipulates and transforms data represented as physical (electronic) quantities.

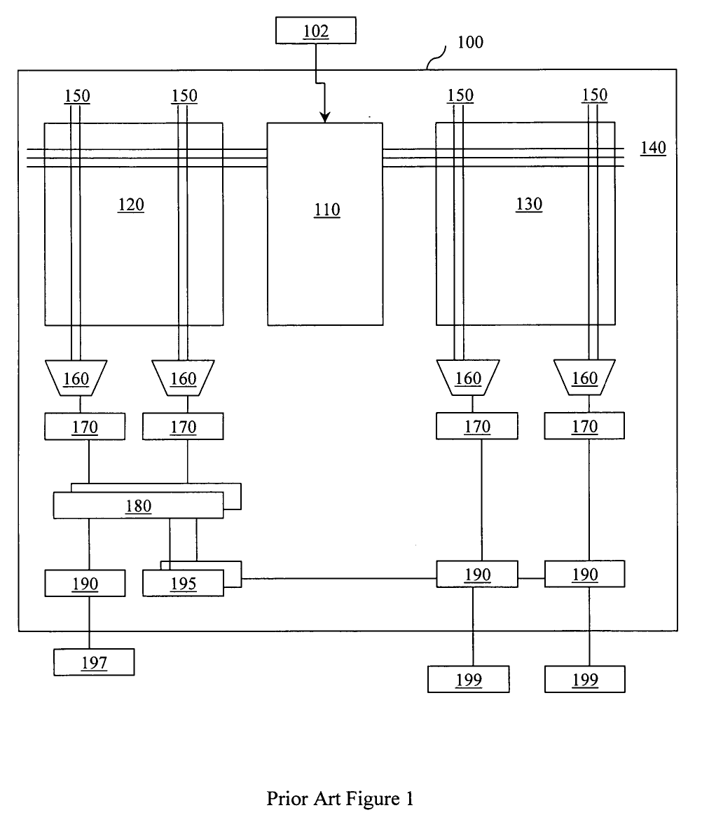

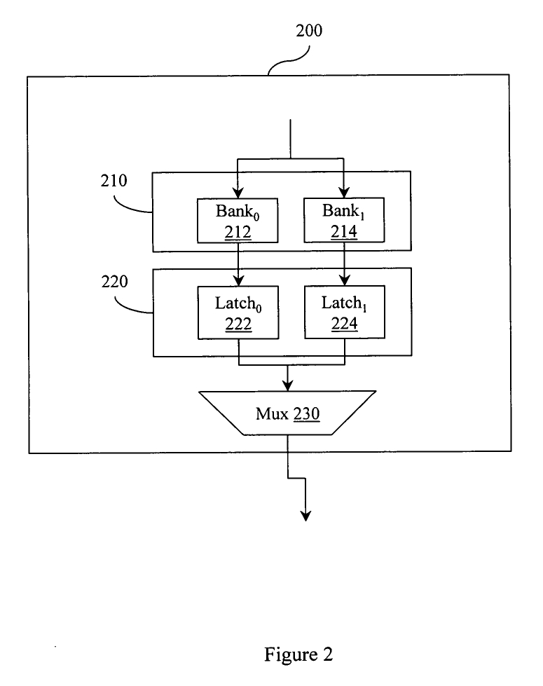

FIG. 2 illustrates an example cache 200. Cache 200 may include an array 210 that is physically banked into a set of banks. In one example, array 210 may be a tag array. In FIG. 2, array 210 is banked into two banks, bank₀ 212 and bank₁ 214. While two banks are illustrated, it is to be appreciated that in other examples a greater number of banks may be employed. Cache 200 may be associated with a component like a microprocessor that is operating at a first frequency (e.g., chip frequency). As described above, array 210 may not be able to be accessed at that chip frequency. For example, an access to array 210 may take a period of time equal to X cycles at the chip frequency, X being an integer greater than one. For example, array 210 may take two cycles to be accessed.

Thus, cache 200 may include a set 220 of latches arranged at the logical edge of the array 210. Members of the set 220 of latches may be operably connected to members of the set of banks in array 210 in a one-to-one arrangement where each bank is connected to exactly one latch and each latch is connected to exactly one bank. A latch may be configured to store a value provided by a bank. Thus, during a first period of time bank₀ 212 may be accessed and the value retrieved may be stored in latch₀ 222. Similarly, during a second period of time bank₁ 214 may be accessed and the value retrieved may be stored in latch₁ 224. Therefore, by switching between the latches outputs may be provided in response to inputs received at a higher frequency than that at which array 210 may be accessed. If the number of banks equals or exceeds the number of cycles required to access array 210, then cache 200 may appear to handle inputs at a higher rate (e.g., the chip frequency). While latches 222 and 224 are illustrated as separate components in FIG. 2, it is to be appreciated that latching may be a logical function and/or a function of timing of components in cache 200. For example, latches 222 and 224 may simply be sense amplifiers included in cache 200 if multiplexer 230 can be controlled to look at an appropriate bank in array 210 at an appropriate time.

For example, the array 210 may be operating at a first frequency FREQ/2 and multiplexer 230 may be operating at a second frequency FREQ. During a first cycle in array 210 a differential may form on bitlines and during a second cycle a sense amplifier may be enabled and data may propagate out of array 210. If the propagation is fast enough then the data may reach the boundary of array 210 quick enough to pass through multiplexer 230 and/or other logic before being latched.

To facilitate using the latches 220 to provide this appearance of handling inputs at a higher rate than any individual bank can handle, cache 200 may include a multiplexer 230 that is operably connected to the set 220 of latches or directly to the array 210. The multiplexer 230 may be configured to provide a data value from a selected bank or from a selected latch to facilitate matching an output from the multiplexer 230 with a specific input to cache 200.

By way of illustration, inputs may be received in cache 200 at a chip frequency but accessing array 210 may occur at half the chip frequency and thus take two clock cycles at the chip frequency. A first input may cause a first bank (e.g., bank₀ 212) to be accessed and a first value to be retrieved and to be stored in a first latch (e.g., latch₀ 222) and/or to be available to multiplexer 230. While the first bank is being accessed, which in this example takes two clock cycles, a second input may cause a second bank (e.g., bank₁ 214) to be accessed and a second value to be retrieved and stored in a second latch (e.g., latch₁ 224) and/or to be available to multiplexer 230. Since the two banks are independent, the accesses may occur substantially in parallel (e.g., one clock cycle out of phase). At a point in time when the first value is available and the second value is being retrieved the multiplexer 230 may select a first latch or bank and provide the first value to a downstream component. The first value may be provided at a time that cache 200 has declared it will provide a response to an input. The time may be, for example, m clock cycles after an associated input request, m equaling precode/decode delay+bank selection delay+bank access time+latching time+multiplexer control time. At a later point in time when the second value is available the multiplexer 230 may select the second latch or bank and provide the second value to the downstream component. The second value may also be provided at a time (e.g., m clock cycles after an associated input request) that cache 200 has declared it will provide a response to an input. Thus, by switching between banks, latching retrieved values, and using the multiplexer 230 to selectively provide latched retrieved values, cache 200 can appear to handle input requests at a rate higher than array 210 can handle any individual request. Similar results may be achieved without separate latches 220 by controlling multiplexer 230 to provide a value from a bank in array 210 at a desired time. In this case the time may be n clock cycles after an associated input request, n equaling precode/decode delay+bank selection delay+bank access time+multiplexer control time.

In one example, cache 200 may include one set of global input lines that may carry addresses, data, and control information, for example. Individual input lines may be operably connected to individual banks in a one-to-one arrangement. Thus, each input line may be connected to one bank and each bank may be connected to one input line. Thus, banks in array 210 may receive input information substantially simultaneously. Similarly, cache 200 may include one set of global output lines that may carry data and control information, for example. Individual output lines may be operably connected to individual banks in a one-to-one arrangement. Thus, each output line may be connected to one bank and each bank may be connected to one output line. The output lines may also be connected to multiplexer 230. Thus, multiplexer 230 may receive information provided by latches 220 and/or array 210 substantially simultaneously. With these global input lines, global output lines, and the multiplexer 230 available, cache 200 may receive inputs at a frequency higher than array 210 can handle any individual request. The illusion may be made more complete by clocking the multiplexer 230 at the higher (e.g., chip) frequency.

As described above, “latch” describes a function more than an individual electronic component. Thus, in one example, the latches 220 may be word line drivers configured to operate using pulse technology. A word line driver using pulse latch technology may be a dynamic driver with full feedback having a small finite period of time associated with a pulse during which the line driver may be evaluated before a subsequent clock cycle drives the line driver to a different state. Similarly, in another example the latches 220 may be sense amplifiers.

While cache 200 illustrates an array 210 with two banks and discusses array 210 operating at half the chip frequency, different numbers of banks and relationships between chip frequency and array access cycles may be employed. In one example, cache 200 may have two banks that operate at half the chip frequency. In different examples, cache 200 may have four banks that operate at half the chip frequency or four banks that operate at one quarter of the chip frequency.

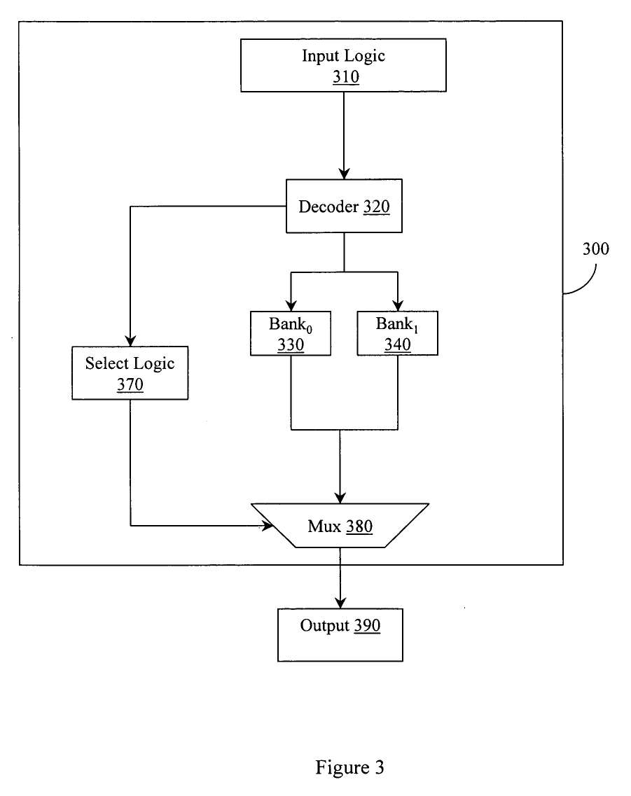

FIG. 3 illustrates an example cache 300. Cache 300 includes a multiplexer 380 like multiplexer 230 (FIG. 2), and an array physically banked in multiple banks (e.g., bank₀ 330, bank₁ 340). While two banks are illustrated, it is to be appreciated that cache 300 may have a greater number of banks.

Cache 300 also includes an input logic 310 that is operably connected to the banks. In the illustration, the operable connection traverses a decoder 320. Decoder 320 may be configured to separate out word line information, bit line information, bank information, and so on. The inputs and/or portions of the decoded information may be made available substantially simultaneously to the banks.

The input logic 310 may be configured to receive a request to access the array. The request may be, for example, a request to read a value from a location, to store a value in a location, and so on. Requests may be received at the input logic 310 at a first rate determined by a first frequency (e.g., chip frequency). For ease of illustration, the time when a request is received may be referred to as a time T₀. While a single request is described, it is to be appreciated that input logic 310 may receive multiple requests in serial and that each request may have its own T₀.

The input logic 310 may be configured to facilitate selecting at a time T₁, based on the request, one bank to handle the request. T₁ is a time after T₀. Consecutive times (e.g., T_{N}, T_{N+1}) may be separated by a period of time equal to one clock cycle. To facilitate having cache 300 handle requests at a rate higher than an individual bank could handle, the input logic 310 may be configured to not select the same bank twice in a row. Since multiplexer 380 may be tasked with later providing a value associated with a request received at a time T₀, information from input logic 310 and/or decoder 320 may be provided to a select logic 370. Select logic 370 may facilitate controlling multiplexer 380.

For example, select logic 370 may be configured to control multiplexer 380 to select a bank that was selected at the time T₁ in response to the input received at T₀. If the banks require X cycles to perform an access, then they will provide their output at a time T_{(X+2)}. Thus, the select logic 370 may be configured to control the multiplexer 380 to provide an output 390 at a time T_{(X+3)}. The output may be, for example, a data value retrieved in response to the request received at the time T₀. Therefore, the multiplexer 380 is in effect “looking back in time” to retrieve the information generated in response to a particular input provided to input logic 310. While there may be a delay of several clock cycles between the input arriving at input logic 310 and output 390 being provided, inputs can be provided and corresponding outputs provided in sequence at a higher frequency than would be possible if cache 300 had an individual bank operating below the arrival frequency. It is to be appreciated that the timing described in association with FIG. 3 is illustrative and that other caches configured with multiple banks, logical edge latches and a multiplexer for selecting outputs may employ different timing sequences.

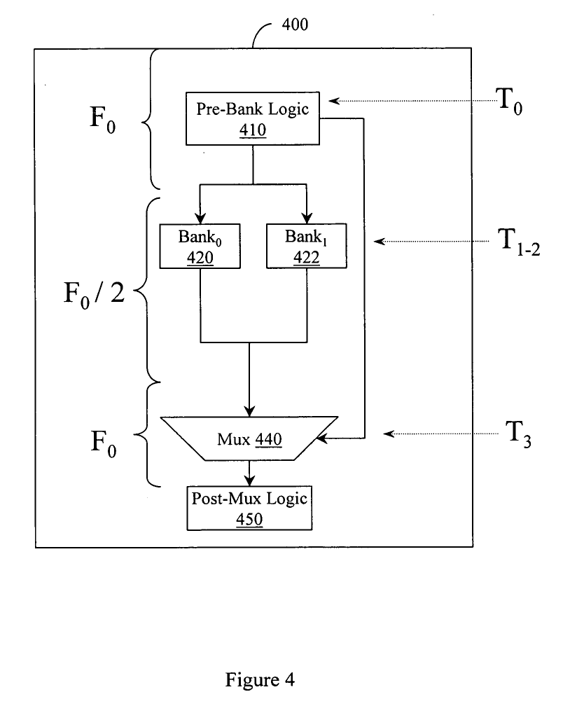

FIG. 4 illustrates an example cache 400 with example timing and frequency information annotated. In cache 400, input logic 310 (FIG. 3) and decoder 320 (FIG. 3) have been consolidated into a pre-bank logic 410. Pre-bank logic 410 may also perform other functions in cache 400. These functions may include processing performed before a bank is accessed. Thus, the time at which these functions are performed may be referred to as a time T₀. It is to be appreciated that time T₀ may consume one or more clock cycles available to cache 400. In one example, pre-bank logic 410 may be clocked at a first frequency F₀. F₀ may be, for example, a chip frequency. “Chip frequency” may refer, for example, to a frequency at which a microprocessor with which cache 400 is associated is clocked.

Cache 400 may also include a post-multiplexer logic 450 that is configured to perform actions including error correction code checking, and tag comparing, for example. Post-multiplexer logic 450 and multiplexer 440 may also be clocked at the first frequency F₀.

In cache 400, the array is divided into two banks, bank₀420 and bank₁ 422. As described above, for reasons like memory switching speeds the banks may not be clocked at the same rate as other components. In FIG. 4 the banks are illustrated being clocked at a divided down rate of F₀/2. Thus, it will take the banks a period of time equal to at least two clock cycles to be accessed and provide a value. The values may be provided to the multiplexer 440. It will be appreciated that different elements in cache 400 may be clocked at different rates. Since there are two independent banks that may operate substantially in parallel in cache 400, and since the banks can be accessed in two clock cycles, cache 400 may accept requests at the F₀ rate and provide outputs at the F₀ rate after a delay equal to the processing time consumed by the elements of cache 400.

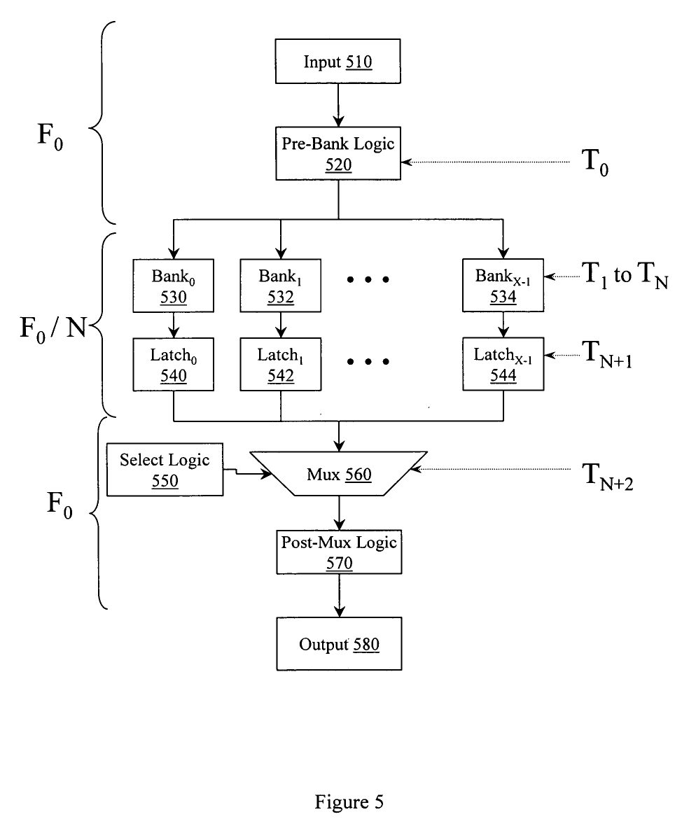

FIG. 5 illustrates elements of an example cache. The cache includes elements like those described in FIG. 2 through FIG. 4. For example, inputs 510 are provided to a pre-bank logic 520 that distributes the inputs and/or other information (e.g., addresses, control, data) to an array that includes a number of banks. In FIG. 5 the array has X banks, bank₀ 530, and bank₁ 532 through bank_{X-1} 534. These banks are operably connected to X latches, latch₀ 540, and latch, 542 through latch_{X-1} 544. A select logic 550 controls multiplexer 560 to provide a selected data to post-multiplexer logic 570 which may then provide an output 580. As described above, the “latching” performed by latches 540 through 544 may be performed by a component like a word line driver, a sense amplifier, and so on.

The inputs 510 may be provided to the pre-bank logic 520 at a first frequency F₀. Similarly, the outputs 580 may be provided from the multiplexer 560 via the post-multiplexer logic 570 at the first frequency. However, the banks are illustrated consuming N cycles per access. Since the banks require N cycles per access, the banks may be clocked at a slower rate of F₀/N. Since there are X banks, up to X requests may be at different points in the N cycles per access. Thus, so long as X is greater than or equal to N, the cache may accept inputs and provide outputs at the higher F₀ frequency.

Example methods may be better appreciated with reference to flow diagrams. While for purposes of simplicity of explanation, the illustrated methodologies are shown and described as a series of blocks, it is to be appreciated that the methodologies are not limited by the order of the blocks, as some blocks can occur in different orders and/or concurrently with other blocks from that shown and described. Moreover, less than all the illustrated blocks may be required to implement an example methodology. Blocks may be combined or separated into multiple components. Furthermore, additional and/or alternative methodologies can employ additional, not illustrated blocks. While the figures illustrate various actions occurring in serial, it is to be appreciated that in different examples, various actions could occur concurrently, substantially in parallel, and/or at substantially different points in time.

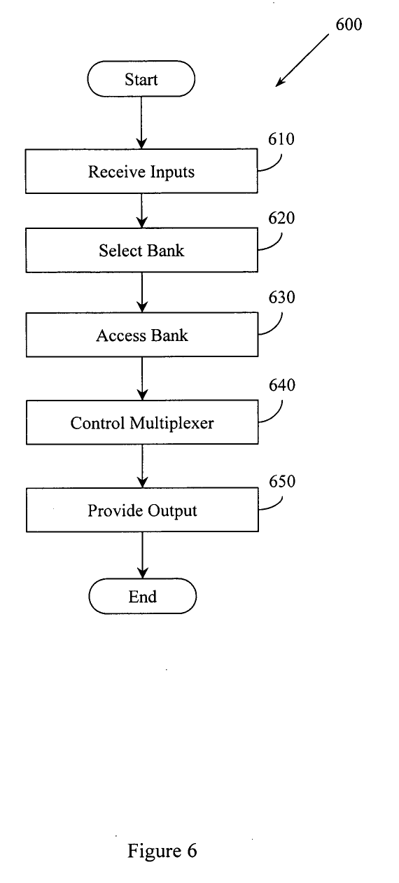

FIGS. 6 through 8 illustrates example methodologies associated with a banked cache having logical edge latches and a multiplexer. The illustrated elements denote “processing blocks” that may be implemented in logic. Processing blocks may represent functions and/or actions performed by functionally equivalent circuits including an analog circuit, a digital signal processor circuit, an application specific integrated circuit (ASIC), or other logic device for example. These figures are not intended to limit the implementation of the described examples. Rather, the figures illustrate functional information one skilled in the art could use to design/fabricate circuits to perform the illustrated processing.

FIG. 6 illustrates an example method 600 associated with a banked cache. Method 600 may include, at 610, receiving a set of inputs. An input may include, for example, an address associated with a cache memory access. The input may seek to read from a location, write to a location, and so on. Thus, different inputs may include different combinations of data, address, and/or control information. In one example, inputs may be received at a first rate and banks in the banked array may be accessed at a second rate that is slower than the first rate.

When an input is received, method 600 may, at 620, select one bank of two or more banks in a banked array in a cache to handle the input. To facilitate achieving the appearance of a cache that can receive inputs at a higher rate than any individual bank can actually handle, the bank may be selected so that no two consecutive inputs are handled by the same bank. The bank may be selected based, at least in part, on an address in the input.

Having selected the bank, method 600 may proceed, at 630, to access the selected bank and to provide an output in response to accessing the bank. In one example, the output may be latched into a member of a set of latches that are operably connected to the banked array. The member of the set of latches may correspond to and be operably connected to the selected bank.

Method 600 may also include, at 640, controlling a multiplexer that is operably connected to the set of banks in the banked array to provide a value from a specific bank. The specific bank will be selected to facilitate pairing a cache memory output with a particular input received at 610. Since a banked cache may be processing several inputs at once substantially in parallel but out of phase, and since a bank in a banked cache may require multiple clock cycles to complete its access, the multiplexer may be controlled at 640 to correlate a specific bank output with a specific received input. Method 600 may also include, at 650, providing an output. The output may be, for example, a data value retrieved from a bank.

To facilitate understanding a sample sequence of events associated with method 600 consider a first input as being received at a time T₀. Thus method 600 may include selecting at a later time T₁ one bank in a banked cache array to handle the first input. Since the banks may require multiple cycles (e.g., X cycles) to access, method 600 may include accessing the bank selected at time T₁ at times T₂ through T_{(X+2)} in response to the first input, X being an integer greater than zero, X describing how many cycles are required to access a bank.

Continuing with this timing example, method 600 may include, controlling the multiplexer at a time T_{(X+3)} and providing the value at a time T_{(X+4)}, the value being related to the first input received at time T₀.

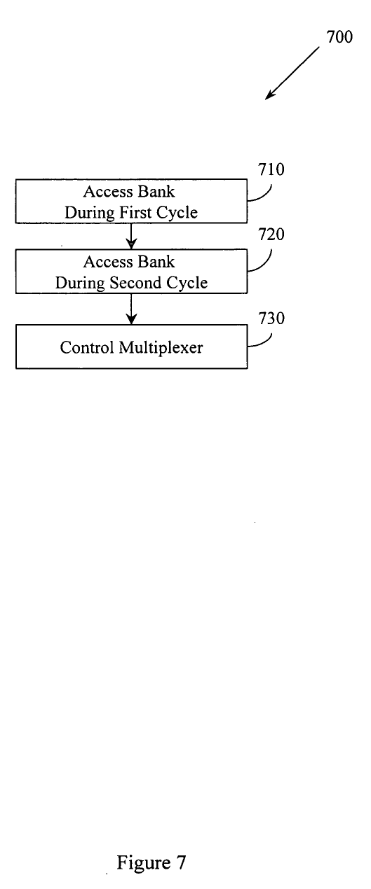

FIG. 7 illustrates an example method 700 associated with a banked cache whose banks require two cycles to be accessed. At 710, a bank may be accessed during a first cycle and at 720 the bank may be accessed during a second cycle. After the two cycles have completed, an output provided from the bank may be provided. In a system running method 700, multiple banks may be available. Therefore, at 730, a multiplexer may be controlled to provide an output corresponding to a particular input.

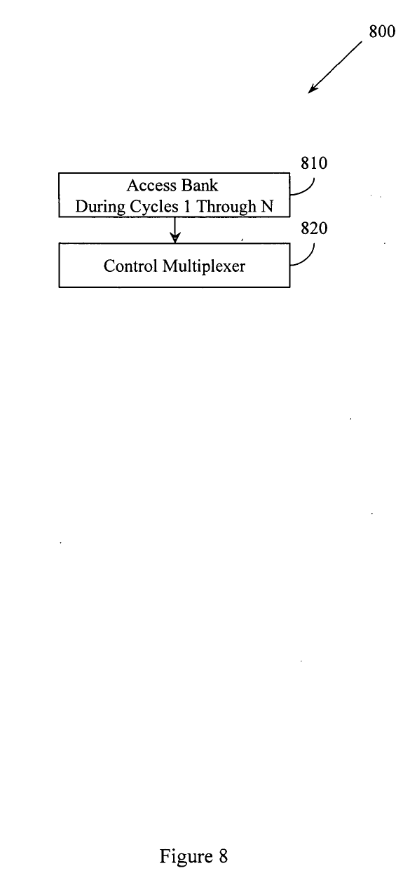

FIG. 8 illustrates a more general example method 800 associated with a banked cache whose banks require N cycles to access. The N cycle access occurs at 810, the value produced by the N cycle access is provided and a multiplexer is controlled at 820 to facilitate providing an output related to a specific input that initiated the N cycle access at 810.

While example systems, methods, and so on have been illustrated by describing examples, and while the examples have been described in considerable detail, it is not the intention of the applicants to restrict or in any way limit the scope of the appended claims to such detail. It is, of course, not possible to describe every conceivable combination of components or methodologies for purposes of describing the systems, methods, and so on described herein. Additional advantages and modifications will readily appear to those skilled in the art. Therefore, the invention is not limited to the specific details, the representative apparatus, and illustrative examples shown and described. Thus, this application is intended to embrace alterations, modifications, and variations that fall within the scope of the appended claims. Furthermore, the preceding description is not meant to limit the scope of the invention. Rather, the scope of the invention is to be determined by the appended claims and their equivalents.

To the extent that the term “includes” or “including” is employed in the detailed description or the claims, it is intended to be inclusive in a manner similar to the term “comprising” as that term is interpreted when employed as a transitional word in a claim. Furthermore, to the extent that the term “or” is employed in the detailed description or claims (e.g., A or B) it is intended to mean “A or B or both”. When the applicants intend to indicate “only A or B but not both” then the term “only A or B but not both” will be employed. Thus, use of the term “or” herein is the inclusive, and not the exclusive use. See, Bryan A. Garner, A Dictionary of Modern Legal Usage 624 (2d. Ed. 1995).

To the extent that the phrase “one or more of, A, B, and C” is employed herein, (e.g., a data store configured to store one or more of, A, B, and C) it is intended to convey the set of possibilities A, B, C, AB, AC, BC, and/or ABC (e.g., the data store may store only A, only B, only C, A&B, A&C, B&C, and/or A&B&C). It is not intended to require one of A, one of B, and one of C. When the applicants intend to indicate “at least one of A, at least one of B, and at least one of C”, then the phrasing “at least one of A, at least one of B, and at least one of C” will be employed.

What is claimed is:

1. A cache memory, comprising:
an array physically banked into a set of N banks, N being an integer greater than one, an array access taking X cycles at a first frequency, X being an integer greater than one; and
a multiplexer operably connected to the set of N banks, the multiplexer being configured to provide a data value from a selected bank, the data value being associated with an earlier access to a member of the set of N banks.

2. The cache memory of claim 1, comprising:
an input logic operably connected to the array, the input logic being configured to receive at the first frequency at a time To a request to access the array, the input logic being configured to facilitate selecting at a later time T₁, based on the request, one member of the set of N banks to handle the request, the input logic being configured to not select the same member of the set of N banks consecutively.

3. The cache memory of claim 2, comprising:
a select logic configured to control the multiplexer to select a bank that was selected at the time T₁ and to provide at a time T_{(X+3)} a data value retrieved in response to the request received at the time T₀.

4. The cache memory of claim 1, including a set of N latches arranged at the logical edge of the array, members of the set of N latches being operably connected to members of the set of N banks in a one-to-one arrangement, a latch being configured to store at a time T_{(X+3)} a value provided by a bank at a time T_{(X+2)}.

5. The cache memory of claim 4, the multiplexer being configured to provide at a time T_{(X+4)} a data value retrieved in response to the request received at the time T₀.

6. The cache memory of claim 5, the latches being one of, word line drivers configured to operate using pulse technology, and sense amplifiers.

7. The cache memory of claim 1, the array being a tag array.

8. The cache memory of claim 1, comprising:
a set of N global input lines, members of the set of N global input lines being operably connected members of the set of N banks in a one-to-one arrangement; and
a set of N global output lines, members of the set of N global output lines being operably connected to members of the set of N banks in a one-to-one arrangement.

9. The cache memory of claim 1, the multiplexer being configured to operate at the first frequency.

10. The cache memory of claim 9, comprising a post-multiplexer logic configured to perform one or more of, error correction code checking, and tag comparing.

11. The cache memory of claim 1, N being 2, X being 2.

12. The cache memory of claim 2, N being 4, X being 2.

13. A cache memory, comprising:
an array physically banked into a set of N banks, N being an integer greater than one, an array access taking X cycles at a chip frequency, X being an integer greater than one;
a set of N global input lines, members of the set of N global input lines being operably connected to corresponding members of the set of N banks in a one-to-one arrangement;
a set of N global output lines, members of the set of N global output lines being operably connected to corresponding members of the set of N banks in a one-to-one arrangement;
an input logic operably connected to the array, the input logic being configured to receive at the chip frequency at a time T₀ a request to access the array, the input logic being configured to facilitate selecting at a time T₁ based on the request one member of the set of N banks, the input logic being configured to not select the same member of the set of N banks consecutively;
a set of N latches arranged on the logical edge of the array, members of the set of N latches being operably connected to corresponding members of the set of N banks in a one-to-one arrangement, the set of N latches being configured to operate at the chip frequency, a latch being configured to store at a time T_{(X+3)} a value provided by a bank at a time T_{(X+2)}, a latch being implemented as a word line driver;
a multiplexer operably connected to each member of the set of N latches by a member of the set of N global output lines, the multiplexer being configured to operate at the chip frequency and to provide at a time T_{(X+4)} a value from a selected latch, the value being retrieved in response to the request received at the time T₀; and
a select logic configured to control the multiplexer to select a latch associated with a bank that was selected at the time T₁.

14. A method, comprising:
receiving a set of inputs, an input including an address associated with a cache memory access; and
for a member of the set of inputs:
selecting one bank of two or more banks in a banked array in a cache to handle the member of the set of inputs based, at least in part, on the address;
accessing the one bank; and
controlling a multiplexer that is operably connected to the two or more banks to provide a value from a bank selected to facilitate pairing a cache memory output with the member of the set of inputs.

15. The method of claim 14, the set of inputs being received at a first rate, banks in the banked array being configured to be accessed at a second rate, the second rate being slower than the first rate.

16. The method of claim 15, a first input being received at a time T₀ and including selecting at a time T₁ one bank to handle the first input.

17. The method of claim 16, the bank being accessed at times T₂ through T_{(X+2)} in response to the first input, X being an integer greater than zero.

18. The method of claim 17, the multiplexer being controlled at a time T_{(X+3)} and the value being provided at a time T_{(X+4)}, the value being related to the first input received at time T₀.

19. A system, comprising:
means for receiving requests to access a banked cache memory at a first rate;
means for accessing a bank in the banked cache memory at a second rate that is slower than the first rate; and
means for synchronizing an output from the banked cache memory to provide at a desired time an output produced in response to receiving a corresponding request.

20. A method, comprising:
performing a first cycle of a two cycle access of a bank;
performing a second cycle of the two cycle access; and
controlling a multiplexer to facilitate providing an output at a time related to an input that initiated performing the two cycle access.

21. A method, comprising:
performing a first cycle of an N cycle access of a bank, N being an integer greater than two;
performing a second through an Nth cycle of the N cycle access; and
controlling a multiplexer to facilitate providing an output at a time related to an input that initiated performing the N cycle access.
